(19) United States
(12) Patent Application Publication
(10) Pub. No.: US 2002/0091981 A1
(43) Pub. Date: Jul. 11, 2002

(54) Method and system for flexible chip and board data transmission

(76) Inventors: Erik Andersen, San Diego, CA (US); Jens C. Michelsen, Karlebo (DK)

Correspondence Address: BLAKELY SOKOLOFF TAYLOR & ZAFMAN, 12400 WILSHIRE BOULEVARD, SEVENTH FLOOR, LOS ANGELES, CA, 90025, US

(21) Appl. No.: 09/757,321

(22) Filed: Jan. 9, 2001

(51) Int. Cl. H03M 13/00

(52) U.S. Cl. 714/752

(57) ABSTRACT

Hardware for communicating between at least two circuits via a serial communication link. The two circuits have interfaces for receiving or transmitting data cells. The hardware supports a first in first out (FIFO) protocol.

### BACKGROUND OF THE INVENTION

1. Field of the Invention

The present invention relates to data transmission, and specifically to a method and system for a data transmission interface and protocol between integrated devices.

2. Description of the Related Art

Data transmission is the transfer of electrical signals over a medium such as a printed circuit board (PCB), copper wire, and air for a wireless application. In the design of electronic devices, the transmission of electrical signals presents significant problems. A major concern is the electromagnetic interference (EMI) generated by each line carrying transistor-to-transistor logic levels (TTL). As the internal circuitry of electronics become more complex, the number of lines increases along with the speed of data transmission on those lines. Both factors increase the EMI emitted by the internal circuitry.

For example, a typical application specific integrated circuit (ASIC) faces various noise problems. An ASIC chip is designed for a particular application, for example a video game chip, and is designed by utilizing existing circuit building blocks. A typical ASIC could utilize a wide parallel interface to an external driver. The wide parallel interface is designed in low voltage transistor-to-transistor logic (LVTTL) and the external driver integrates the parallel interface to a low voltage differential signaling chip (LVDS). However, the addition of the external driver and the wide parallel interface to the ASIC chip increases the cost of the ASIC design because of additional design logic and additional pins for the parallel interface. Also, the wide parallel interface increases the noise due to the larger amount of pins switching logic states and the reduced margin of the LVTTL design. LVDS is a low noise, low power, and low amplitude method for high speed transmission and is set forth in Electronic Industries Association (EIA) document TIA/EIA-644.

Another concern with data transmission is the complexity of integrating various data transmission protocols and interfaces. There are various data transmission protocols with different standards, such as asynchronous transfer mode (ATM) and asymmetric digital subscriber line (ADSL). Each protocol offers competing standards and methods of transmitting data. For example, ATM transmits data in cells or packets of fixed size with a fixed channel or route and results in a direct connection between two points. ATM allows transmitting audio, video, and computer data over the same network and prevents one single type of data of dominating the network connection. However, ATM has the disadvantage of adaptability to sudden surges of network traffic due to the fixed nature of the protocol. Another data transmission protocol is ADSL, which allows higher data transfer rates over existing copper lines. However, ADSL requires a special modem and allows a higher data transfer only when receiving data.

### BRIEF DESCRIPTION OF THE SEVERAL VIEWS OF THE DRAWINGS

The present invention is illustrated by way of example and not limitation in the following figures. Like references indicate similar elements, in which:

FIG. 1 illustrates a system utilized by an embodiment of the present invention.

FIG. 2 illustrates a data flow utilized by an embodiment of the present invention.

FIG. 3 illustrates a communication system utilized by an embodiment of the present invention.

### DETAILED DESCRIPTION OF THE INVENTION

A method and a system for a data transmission interface and protocol between integrated devices are described. In the following description, for purposes of explanation, numerous details are set forth in order to provide a thorough understanding of the present invention. However, it will be apparent to one skilled in the art that these specific details are not required in order to practice the present invention.

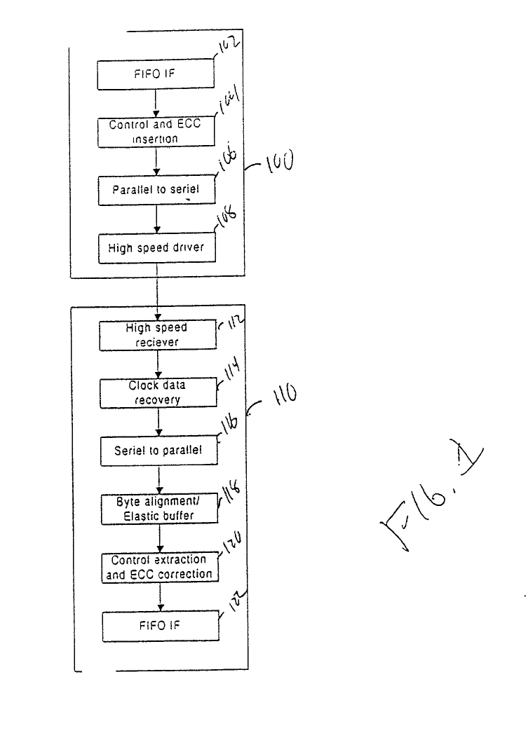

FIG. 1 illustrates a system utilized by an embodiment of the present invention. FIG. 1 illustrates integrated devices 100 and 110. The integrated device 100 and 110 transmit and receive data cells. In one embodiment, integrated device 100 transmits the data cells to integrated device 110. In another embodiment, integrated device 110 transmits the data cells to integrated device 100. In yet another embodiment, both integrated devices 100 and 110 are capable of both transmitting and receiving data cells. The method and system for transmitting data cells between integrated devices 100 and 110 are discussed in the next several paragraphs.

Within integrated device 100, a data cell is presented to a first in first out (FIFO) interface 102 and the data cell is forwarded to a control and error correcting code (ECC) insertion block 104 where ECC bits are added to the data cell. The data cell is forwarded to a parallel to serial block 106 for conversion to smaller data cell chunks. Finally, a high speed driver 108 transmits the data cell chunks to the integrated device 110. The integrated device 100 receives the data cell and performs complementary steps to retrieve the data bits out of the data cell.

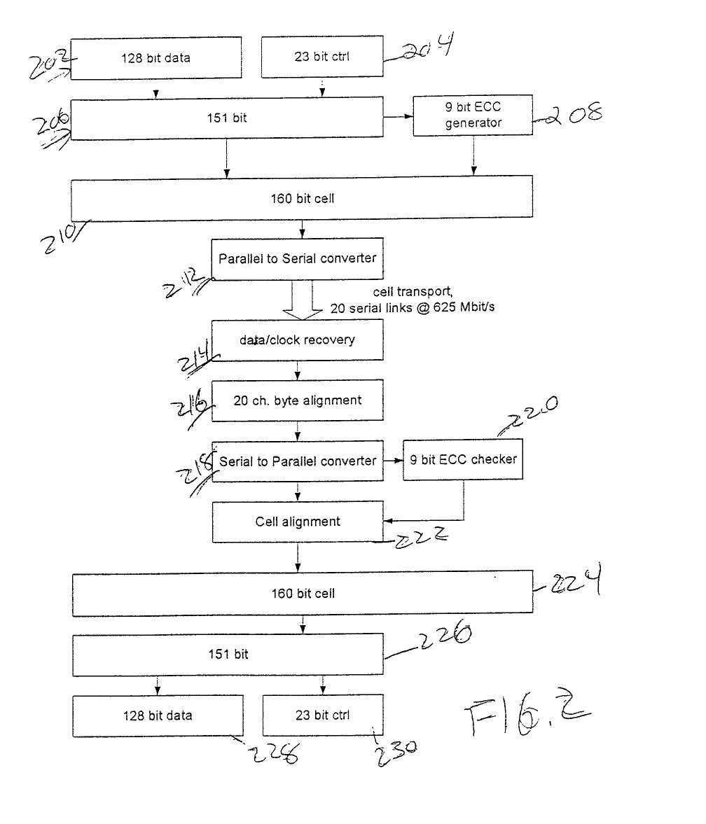

The integrated device 100 transmits the data cells by a first in first out protocol in the FIFO interface 102. The first in first out protocol is a method of outputting the data cells in the order of receiving them. The FIFO interface 102 forwards the data cell to the ECC insertion block 104 and ECC bits are added to the data cell to insure data integrity. The ECC bits are coded and added before transmission of the data cell and upon receiving the data cell are decoded to determine if any of the bits in the data cell have “flipped” to another state. A bit can flip from logic 0 to logic 1 or vice versa due to noise, power surge, and clock jitter. The ECC is capable of detecting if two bits have flipped and can correct one bit. If the ECC detects two bits have flipped, the data cell is marked bad and is not used. After the ECC bits are added to the data cell, the data cell is forwarded to the parallel to serial block 106. The parallel to serial block 106 converts the data cell into smaller chunks to allow for faster transmission. The data transmission and the conversion within the parallel to serial block 106 are further discussed below with reference to FIG. 2. The high speed driver 108 is a differential output driver and transmits the serial bits of the data cells from integrated device 100 to a high speed receiver 112 within the integrated device 100. The high speed driver is capable of transmitting the data cell at a rate of 2.5 gigabits a second (Gbits/s). The high speed driver supports the output voltage levels as set forth in the Institute of Electrical and Electronic Engineers (IEEE) standard 1596.3-1996.

A high speed receiver 112 within the integrated device 110 receives the data cell from the integrated device 100. The high speed receiver comprises a differential input and utilizes LVDS to interpret the serial bits of the data cell. A clock data recovery block 114 samples the data cells by verifying the clock transitions and validates the clock integrity. The data cell is forwarded to a serial to parallel block 116, which converts the serial bits of the data cell to a single parallel word of data. The initial parallel word of data was divided into smaller chunks of serial bits in block 106 to allow for faster data transmission. To allow the data to be used within integrated device 110, the smaller chunks of serial bits are combined to a single parallel word of data. A byte alignment and elastic buffer block 118 aligns the various serial channels used in transmitting the data cell to the integrated device 110 by transmitting training bytes through the serial link and verifying the integrity of the training bytes. An elastic buffer is utilized to receive clock signals if more than one serial channel alignment is needed. After the training bytes are received and verified, the data cells are transmitted. During the actual data transmission, rather than the training bytes, the data link is periodically checked. If a certain threshold of ECC errors are detected, a resync operation is performed which consists of downing the link, checking the data cells, and sending training bytes. If the training bytes are received correctly, the data link is turned on and allowed to start transmitting real data cells.

The data cell is forwarded to a control extraction and ECC correction block 120. The control bits are extracted from the data cell and the ECC is validated. If the ECC does not detect errors or can correct a one bit error, the data cell is accepted. If the ECC detects more than a one bit error, the data cell is marked bad and is not used. If the data cell is accepted, a status signal is set to “filled” in a FIFO interface 122. Otherwise, the status signal is set to “non-filled” in the FIFO interface 122.

FIG. 2 illustrates a data flow utilized by an embodiment of the present invention. The data flow illustrates the formation of the data cell within the integrated device 100 and the reception of the data cell within the integrated device 110. Also, the data flow illustrates the transmission of the data cell between integrated devices 100 and 110. The data flow incorporates a discussion of the various blocks in FIG. 1, which are utilized for the formation of the data cell.

Initially, the data cell is formed in blocks 202, 204 and 206. The data within the data cell is presented to the FIFO interface 102 in FIG. 1 and is illustrated in block 202. In one embodiment, the data is 128 bits. The control and ECC insertion block 104 in FIG. 1 generates the control bits in block 204. The control bits and the data bits from block 202 and 204 are combined to form the data cell in block 206. The ECC bits are generated in block 208 for block 206 by the control and ECC insertion block 104 in FIG. 1. In one embodiment, the control and ECC insertion block generates 23 control bits and 9 ECC bits. The ECC bits are combined with block 206 to form the data cell in block 210. The parallel to serial conversion block 106 in FIG. 1 divides the data cell depicted in block 210 into several smaller chunks. The conversion is depicted in block 212. The high speed driver 108 in FIG. 1 transmits the serial bits from the integrated device 100 to integrated device 110 via the serial links. In one embodiment, twenty serial links transmit at a rate of 625 million bits per second. The data and clock recovery and byte alignment in blocks 214 and 216 perform the clock recovery and byte alignment as discussed with reference to block 114 in FIG. 1. The serial bits are converted back to a parallel format in block 218. The ECC validation and correction are performed in block 220. The ECC validation and correction was discussed with reference to FIG. 1 for block 120. A cell alignment is performed in block 222 by utilizing the ECC bits in block 220 as a delimiter between the cells. The delimiter ECC is found by sliding until the ECC is correct for the data cell. After the cell alignment is performed and if the ECC operation was valid, the data cell in block 224 is equivalent to the data cell in block 210. After extracting the 9 ECC bits, the resulting data cell in block 226 contains 151 bits. The control bits are extracted from block 226 and the resulting received data cell in block 228 is equivalent to the initial data cell in block 202.

Those skilled in the art will further appreciate utilizing various embodiments including data cell formats utilizing different sizes of control bits, ECC bits, serial links, and data bits.

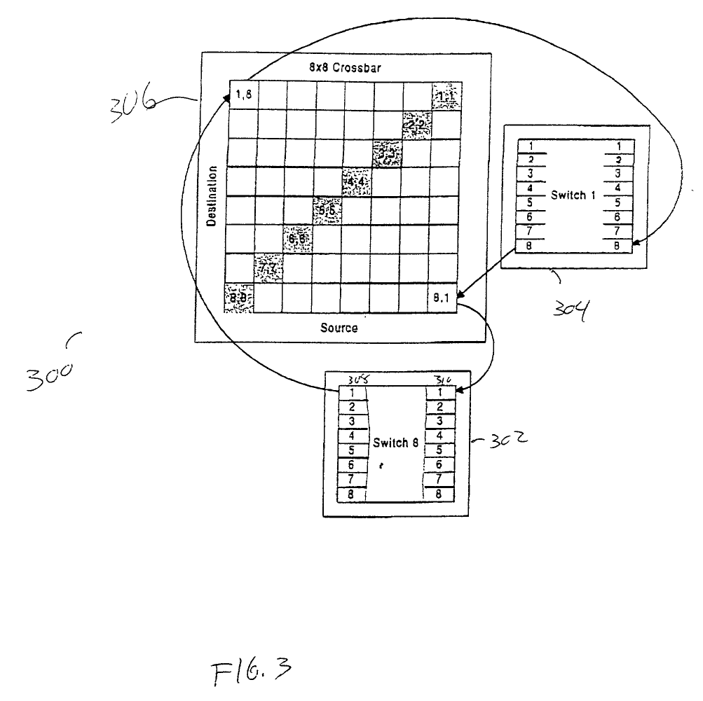

FIG. 3 illustrates a communication system 300 utilized by an embodiment of the present invention. The communication system 300 comprises a first switch engine 302, a second switch engine 304, and a virtual buffer 306. The communication system transfers data cell packets between the switch engines via the virtual buffer in a first in first out protocol.

The switch engines 302 and 304 comprise a plurality of input and output ports. For example, a plurality of output ports 308 is labeled 1-8 and a plurality of input ports 310 is labeled 1-8. The virtual buffer 306 is configured to support one input port and output port, a virtual flow, between the switch engines. In one embodiment, the virtual buffer is a crossbar comprising a plurality of first in first out memories with one crossbar for each virtual flow. The communication system 300, in another embodiment, supports a plurality of crossbars for each virtual flow.

The virtual buffer 306 and first in first out protocol allows for simple configuration and network management because every virtual flow is configured in each crossbar and every combination of input and output port has a virtual flow.

While the invention has been described with reference to specific modes and embodiments, for ease of explanation and understanding, those skilled in the art will appreciate that the invention is not necessarily limited to the particular features shown herein, and that the invention may be practiced in a variety of ways that fall under the scope and spirit of this disclosure. The invention is, therefore, to be afforded the fullest allowable scope of the claims that follow.

1. A system comprising:
a first circuit;
a second circuit;
a serial communication link coupled to the first and second circuit;
a first interface coupled to the first circuit to transmit a data cell of n bits in response to a first in first out protocol; and
a second interface coupled to the second circuit to receive the data cell in response to the first in first out protocol.

2. The system of claim 1 wherein the first interface to transmit the data cell comprises a first converter to divide the data cell of n bits into smaller cells of less than n bits.

3. The system of claim 1 wherein the second interface to receive the data cell comprises a second converter to combine the data cells of less than n bits to generate a data cell of n bits.

4. The system of claim 1 wherein the first interface to transmit the data cell adds a plurality of error correcting bits to the data cell.

5. The system of claim 1 wherein the second interface to receive the data cell extracts a plurality of error correcting bits from the data cell.

6. The system of claim 1 wherein the serial communications link comprises twenty serial channels capable of transmitting 625 million bits a second.

7. A method comprising:
receiving a data cell of n bits in a first integrated device;
receiving a plurality of control bits and error correcting code bits;
appending the plurality of control bits and error correcting code bits to the data cell;
converting the data cell of n bits to a plurality of data cells of less than n bits;
transmitting the plurality of data cells of less than n bits from the first integrated device in a serial format in response to a first in first out protocol; and
receiving the plurality of data cells of less than n bits in a second integrated device.

8. The method of claim 7 further comprising:
re-converting the plurality of data cells of less than n bits to the data cell of n bits.

9. The method of claim 7 wherein transmitting the data cell of the plurality of data cells of less than n bits comprises validating the serial format with a resync operation.

10. The method of claim 8 wherein re-converting the plurality of data cells of less than n bits to the data cell of n bits comprises aligning the data cells of less than n bits in response to the error correcting code bits.

11. The method of claim 8 wherein re-converting the plurality of data cells of less than n bits to the data cell of n bits comprises extracting the control bits from the data cell of n bits

12. A system comprising:
a first network switch comprises a first transmit interface and a first receive interface;
a second network switch comprises a second transmit interface and a second receive interface;
a data cell of n bits; and
a serial communication link coupled to the first and second network switch, to transmit the data cell from the first transmit interface of the first network switch to the second receive interface of the second network switch via a m bit by m bit crossbar buffer in response to a first in first out protocol.

13. The system of claim 12 wherein the first and second transmit interface comprise a converter to divide the data cell into a plurality of data cells of less than n bits.

14. The system of claim 12 wherein the first and second transmit interface generate and append a plurality of control and error correcting code bits to the data cell.

15. The system of claim 12 wherein the first and second transmit interface comprise a low voltage differential signaling encoder.

16. The system of claim 12 wherein the first and second receive interface comprise a low voltage differential signaling decoder.

17. The system of claim 12 wherein the first and second receive interface comprise a re-converter to align a plurality of data cells of less than n bits data cell into the data cell of n bits.
